(19) United States
(12) Patent Application Publication
(10) Pub. No.: US 2013/0276880 A1
(43) Pub. Date: Oct. 24, 2013

(54) TRANSPARENT LAYER COMPOSITE ASSEMBLIES

(71) Applicants: Silke Wolff, Hueckeswagen (DE); Ute Wolfel, Mainz (DE); Simone Ritter, Mainz (DE); Peter Brix, Mainz (DE)

(72) Inventors: Silke Wolff, Hueckeswagen (DE); Ute Wolfel, Mainz (DE); Simone Ritter, Mainz (DE); Peter Brix, Mainz (DE)

(73) Assignee: SCHOTT AG, Mainz (DE)

(21) Appl. No.: 13/882,011

(22) PCT Filed: Oct. 25, 2011
(86) PCT No.: PCT/EP11/68637

§ 371 Date: Jul. 12, 2013

(30) Foreign Application Priority Data
Oct. 26, 2010 (DE) 102010042945.7

(51) Int. Cl. H01L 51/52; H01L 51/44; H01L 51/56

(52) U.S. Cl. CPC H01L 51/5203; H01L 51/56; H01L 51/442
USPC 136/256; 257/40; 438/29; 438/69

(57) ABSTRACT

Transparent layer composite assemblies are provided that are suitable for use in solar modules and light emitting diodes, as well as methods for producing such layer composite assemblies and to the uses thereof. The layer composite assemblies have substrate materials that make it possible to increase the luminous efficiency of light emitting diodes and the efficiency of solar modules.

The present invention relates to transparent layer composite assemblies, suitable for use in light-emitting diodes, preferably with organic semiconductors (OLEDs), and a method for manufacturing such layer composite assemblies.

The development of the classical inorganic light-emitting diode (LED) in the middle of the 20^{th} century, based on the discovery of semiconductors in the early 20^{th} century and their systematic further development, revolutionized the lighting sector of the application area optics/optoelectronics. Properties such as for example extremely long lifespan, high modulation speed, high efficiencies and mechanical insensitivity in comparison to standard hollow luminous bodies complement the advantages of these nearly monochrome cold light sources, which are in the meanwhile available in many wavelength gradations.

A disadvantage of these traditional LEDs, which is particularly important in the sector of display and of extensive lighting, is the inorganic nature of the semiconductor. In order to be able to illuminate extensive areas, respectively to obtain an extensive luminous body, the inorganic material would have to be provided in thin, extensive layers, which causes economical problems due to the complexity of the technical process.

Here, the big advantage of a newer generation of LEDs, the organic light emitting diodes (OLEDs) becomes apparent. Here, an organic semiconductor (emitter layer) is printed flexibly and economically onto a transparent conductive oxide layer, commonly made of indium tin oxide (ITO) (anode), optionally protected with a protective layer against oxygen and water, and provided with an additional conductive metal or alloy layer (cathode). This layer composite assembly constitutes the OLED.

For that, the transparent conductive oxide layer (for example ITO), or another highly conductive and transparent layer (for example graphene) is initially applied to a substrate material, which has to be adapted to the requirements of the ITO-process with regard to its thermal resilience. This substrate is even a superstrate, because the radiation generated in the emitter layer is extracted via this layer.

Thus, usually a glass sheet is used as a substrate, which does not bring with it the mechanical flexibility of a plastic layer, but which has better chemical resistance and satisfies more the thermal demands and thus produces the overall more stable and more durable layer composite assemblies.

Usually, in OLEDs only about 20 to 25% of the light generated in the emitter layer is emitted through the superstrate. A large part of the generated light remains in guided optical modes within the organic layers or in the substrate. A part of this loss of light is attributable to total reflections at the interfaces air/superstrate/anode.

Particularly the total reflection at the interface superstrate/anode is attributable to the difference in the specific refractive indices of the two materials. Usually, soda-lime glass with a refractive index of n_{d}=1.53 is used as a superstrate, an ITO layer however has a refractive index of n_{d}=2.1. Under these prerequisites the total reflection is large. The use of a higher-refracting glass, which is thus preferably adapted with regard to refraction to the anode material, as superstrate material would thus reduce the extent of total reflection considerably and thus considerably increase the efficiency of light extraction clear from the layer composite assembly. Thus, the efficiency of the OLEDs would be optimized in this way both with regard to the absolute light output (brightness/contrast) and with regard to reduced heat load of a possible end product, for example an OLED display.

Glasses with refractive indices in the region above n_{d}=1.5 up to 1.7 are quite known. In the field of technical glasses these are achieved however by adding large amounts of lead oxide, which is ecologically questionable and also disadvantageous for economical large-scale processes. Known classical optical glasses with optical positions in the higher refractive index region, which are used for light and image guides and which thus serve the classical application fields (e.g. imaging, microscopy, medical technology, digital projection, photolithography, optical communications engineering, optics/lighting in the automotive sector), are usually made as a bulk material because of the geometry of their subsequently produced products (lenses, prisms, fibers, etc.). Bar sections from continuous bar production, fiber core glass rods and optical blocks are standard formats of the manufacturing process of optical glasses. 20 mm are considered as economically and applicatively reasonable minimum dimension in the direction of the smallest geometrical extent, usually the thickness (bar sections) or the diameter (fiber core glass rods), desirable are thicknesses starting from 40 mm and optical blocks start only at about 150 mm.

But the selection of the high-refractive substrate glasses has to be restricted with respect to a further optical property in spite of the above indicated advantages of the highest possible refractive index.

Naturally, the wavelength dependence of the refractive index is intrinsic to (optical) glass. This property is called “dispersion” and causes that radiation is split (dispersed) into its spectral components, when a body made of optical material with a refractive index different from 1 is irradiated with non-monochromatic radiation (in the fields of lighting and display mainly light of the UV-vis region of the electromagnetic spectrum; 250-850 nm). In short, when passing through the material, beams of shorter wavelengths are refracted more than those of higher wavelengths. This is widely known because of the prism effect of glass or plastic prisms or also because of the rainbow effect of water. The following rough correlation applies: the higher the refractive index of the material (for example, at a fixed wavelength/spectral line d=587.6 nm), the higher, in general, also the dispersion at this optical line.

In the field of optical glasses the refractive index is denoted by n and the dispersion is denoted by v. The observed spectral lines are indexed by either wavelength information or by defined character encoding (nₓ and vₓ, x: wavelength of observation). This is not a linear relationship, but, depending on the classes, families and types of materials, a relationship further characterized by the properties partial dispersion Px;y (x, y describe the respective cut-off wavelengths of the relevant region) and anomalous relative partial dispersion ΔPx;y. Thus, the dispersion vₓ is not clearly defined by the refractive index nₓ, although the relationship is sufficiently strongly given for this discussion, without the need to regard partial dispersion and anomalous relative partial dispersion.

For the areas of display (propagation of light through a shading matrix/mask) and lighting (homogeneous illumination of a defined area), which both have a significant working distance between projection area/viewer and the light source, dispersion of light in the vicinity of the light source is already problematic for a point-shaped light source, as soon as not only light of a defined wavelength is used, but non-monochromatic light from a single lighting cell or monochromatic light from differently-colored lighting cells arranged closely side by side on the same substrate/superstrate. The short-wavelength components of light are refracted more strongly than the longer-wavelength components and thus in the distance of the optical image, respectively in the image plane, differently sized partial color images are displayed depending on the wavelength: Whether the image is a spot of light in the lighting sector or a defined shape in the display sector, it shows rainbow-like color fringing appearing in its natural structures. Here, the extent of application-impairment is dependent on the sensory acceptance. In high-quality classical optical systems, such as camera lens systems or projectors, highly sophisticated optical designs including a systemically combined plethora of individual lenses of differing optical glasses are used for the so-called color correction. Because this is prohibited due to the implementation in case of a superstrate like the one of the present invention, no correction of potentially occurring color aberrations can take place if the dispersion in the superstrate material is too high.

The desired planar nature of OLEDs as the light source comes into effect additionally. The differently colored partial images of the virtual point light sources superimpose in the planar middle areas so that, at least in the area of display, image sharpness is lost, albeit apparently no wrong color impression emerges from superimposition of the spectral components. At the edges moreover, the described color fringes occur in both application areas.

However, no general optimal dispersion limit can be stated, because the maximally acceptable dispersion in these sectors is, from an applicative point of view, strongly dependent on the system design and the intended application, i.e. the sensory perception and the tolerance of the error. A selection can still occur by compliance with definitely appropriate values.

This results in an additional selection criterion for the high-refractive optical-technical hybrid glasses. They have to have a dispersion as low as possible. Since this condition is in a technical trade-off to the condition of a refractive index as high as possible, and also represents an applicative k.o. criterion, the additional condition of a not too high refractive index becomes automatically obligatory.

Due to the non-unambiguity of the refractive-index-dispersion-correlation (see above) in optical glass and therefore also in the opto-technical hybrid glasses, the following restrictions arise. Glasses with refractive indices of n_{d}<1.8 are naturally of sufficiently low dispersion (Abbe number v_{d} between 23->>70) (the Abbe number becomes smaller as the dispersion rises; inversely-proportional representation of the dispersion). However, glasses with refractive indices of n_{d}≧1.8 may have dispersions in the Abbe number region of v_{d}<15. Here, one has to go back to glasses with lower dispersions. Thus, known optical glass systems that well achieve refractive index regions of n_{d}>2.0, but that at the same time have dispersions up to v_{d}<15, are prohibited in the selection.

Also newer production methods, such as the more economical in situ component production by close-to-final-geometry precision hot forming processes (PHFG), are, at least in contrast to the flat glass processes with a product thickness of usually a few millimeter, included in the bulk glass processes. Due to the bulk production process, these materials are subject to specific conditions, of which the most prominent is the required adjustment of a temperature-viscosity behavior in the glasses that is named “shortness of the glass” in the glassmaking language. This means that the viscosity varies strongly with changing temperatures. In this way, short form-fit times can be achieved in the PHFG as well as rapid form stability, low melting temperatures and fast cooling processes, without having to fear either deficient products caused by stress rupture or uneconomically long process times (melting & cooling).

Classical optical glasses differ in exactly these characteristics from the technical standard glasses, whose physico-chemical property profiles are specifically tailored to the technical framework of, in comparison to the production units of optical glasses, significantly larger production units of technical glasses, namely flat glasses, thin glasses and glass tubes.

Technical glasses usually have a “long” viscosity profile, which means that its viscosity does not vary so much with differing temperature. This results in longer terms of the respective individual processes, as well as overall increased process temperatures, which less pronounced negatively affects the profitability in case of the large aggregates. There are also significantly increased retention times of materials in the aggregates, due to flow conditions and aggregate size. Long glasses are advantageous for continuous large aggregates because these glasses have a greater temperature range at which they can be processed. Thus, the process does not have to be aimed at the fastest possible processing of the still hot glass.

If one was now to produce classical optical materials in a technical standard float glass process (for example drawing, overflow fusion, down draw, rolling or the like), the necessary changes in the property profiles were chemically targeted precisely to the variation or reduction of the components, which give optical glasses their extraordinary properties: For example, reducing TiO₂, ZrO₂ or La₂O₃ did result in longer and less crystallization sensitive glasses, but also in a significant loss of refractive index properties and dispersion properties.

A further complication is that the flat/thin glass process, which is currently favored for economical reasons, namely the float process on a liquid tin bath, imposes certain chemical requirements on “floatable” glasses, which are not satisfied by the classical optical glasses: except for zinc oxide, which acts negatively with respect to secondary crystallization, no redox-active, i.e. no polyvalent components should be present in the glass. Thus, optical standard components, such as the oxides of lead, phosphorus, bismuth, niobium, tungsten as well as the classical polyvalent fining agents, whose effective action is based exactly on the multi-phase shift of the redox equilibrium, are prohibited. Altogether, these two classical material groups, the optical and technical glasses, differ with respect to their processability in an incompatible way.

It is therefore the object of this invention to provide transparent layer composite assemblies, which make it possible to extract the radiation generated in the layer composite assembly with minimal losses.

This was achieved according to the present invention by the creation of a new class of material, which combines the respective advantageous properties of both classical material groups in the sense of an opto-technical hybrid material. These opto-technical hybrid glasses have the advantageous optical properties of homogeneity, refractive index and transmission, and at the same time the hot forming properties suitable for flat glass processes, namely reodx stability, crystallization stability and relative length. As the focus in the flat glass process is very much on the float glass process, the redox stability takes a prominent role here.

The problem is solved by the subject matter of the claims.

The inventive object is achieved in particular by a transparent layer composite assembly, comprising a semiconductor layer, a conductive transparent oxide layer and a substrate layer, wherein the substrate layer comprises an opto-technical hybrid glass having a refractive index n_{d} of >1.6.

In preferred embodiments, the layer composite assembly is used in an OLED, the OLED comprises in addition to the layer composite assembly, a cathode, preferably a cathode layer.

In alternative embodiments, the layer composite assembly of the present invention may also be used in solar modules or as a solar module. It is obvious that with the aid of the glasses used according to the present invention, advantageous properties in the composite layer assembly can be obtained for solar modules as well because it depends also there on the unimpeded passage of light through a glass substrate. Consequently, solar modules with improved efficiency can be obtained using the composite layer assemblies. In such solar modules the composite layer assembly is used together with a cathode as well.

Preferred embodiments of OLEDs with the composite layer assemblies of the present invention have the following structure in the following order:

1. Substrate layer
2. Transparent conductive oxide layer (=anode)
3. Optional layer of PEDOT/PSS
4. Optional hole transport layer (HTL, hole transport layer)
5. Semiconductor layer
6. Optional electron transport layer (ETL, electron transport layer)
7. Optional protective layer
8. Cathode layer

Here, PEDOT/PSS means Poly(3,4-ethylenedioxythiophene)/polystyrenesulfonate; this layer serves to reduce the injection barrier for holes and to prevent diffusion of constituents of the oxide layer into the junction. The optional protective layer preferably comprises lithium fluoride, cesium fluoride or silver, as well as combinations thereof.

The opto-technical hybrid glass is preferably producible by a flat glass process. A flat glass process according to the present invention is understood as a process that provides access to glass within the aspect ratio (thickness to surface area) of plates, which is further described below. These plates are characterized by a minimal thickness of 0.5 mm (thinnest glasses) over standard thicknesses of 1 to 3 mm, up to a thickness of 8 mm. Here, glass sheets of up to 10 m width (for example window glass), but usually with widths between 0.3 to 3 m, are produced in continuous process management with a throughput of typically well above 100 tons per day. The type of hot forming process varies with the intended aspect ratio between rolling, drawing and floating, as well as down draw and overflow fusion and related processes. In this way, according to the present invention, the required thickness of the substrate layer is achieved. With conventional optical glasses having a refractive index of >1.6 these flat glass processes cannot be performed because they contain components that do not withstand unchanged the respective conditions in flat glass processes.

The substrate layer in the layer composite assembly has preferably a layer thickness of less than 5 mm. More preferably, this layer thickness is less than 3 mm and more preferably less than 1 mm. The thickness of the substrate layer must not be too large because otherwise the elasticity of the glass would be too low. Moreover, the transmittance decreases with increasing layer thickness. The layer composite assembly in total would be less elastic. If, however, the layer thickness is too small, on the one hand the processability is more complicated, on the other hand the layer composite assembly becomes in total less resistant to damage. Therefore, the layer thickness of the substrate layer is preferably at least 0.1 mm and more preferably at least 0.3 mm.

According to the present invention it is preferred to use an opto-technical hybrid glass, which has a particularly advantageous elasticity. Therefore, the opto-technical hybrid glass preferably has a modulus of elasticity (E-modulus) of at most 120*10³ N/mm², further preferably at most 105*10³ N/mm² and more preferably at most 97*10³ N/mm².

If a glass with a too high E-modulus is used, the advantages of the layer composite assembly, in particular when used as or in an OLED, cannot be fully exhausted. Nonetheless, the substrate layer should impart a certain structural integrity to the layer composite assembly, so that the E-modulus should preferably not be below a value of 60*10³ N/mm², more preferably not below 70*10³ N/mm² and more preferably not below 82*10³ N/mm².

The advantageous elasticity is achieved by appropriate selection of the components of the opto-technical hybrid glass. In particular the network formers in the glasses should be optimized in terms of elasticity. Network formers in particular are SiO₂, B₂O₃, Al₂O₃.

The opto-technical hybrid glasses of this invention preferably comprise SiO₂ in amounts of at least 0.5 wt-%, more preferably at least 3 wt-% and particularly preferably at least 10 wt-%. Particular embodiments include SiO₂ even in amounts of at least 27.5 wt-%. Although SiO₂ reduces the elasticity of the glasses, at the same time it increases their chemical resistance. In order not to affect the elasticity too much, the content of SiO₂ should preferably not exceed a value of 71 wt-%. More preferably, the content of SiO₂ should not exceed a value of 55 wt-%, and most preferably of 45 wt-%.

B₂O₃ reduces the elasticity of the glasses and is also from the point of view of work safety during melting to be used in not to high concentrations. The content of B₂O₃ in the opto-technical hybrid glasses should therefore not exceed a value of 50 wt-%. Preferred glasses contain even only up to 35 wt-% B₂O₃. Particularly preferred glasses contain B₂O₃ in amounts of not more than 25 wt-%, more preferably not more than 15 wt-%, and most preferably not more than 10 wt-%. However, B₂O₃ improves the chemical resistance of the opto-technical hybrid glasses, so that preferred glasses comprise at least 1 wt-%, more preferably at least 5 wt-% and particularly preferably at least 7 wt-% B₂O₃.

Al₂O₃ reduces the elasticity of the opto-technical hybrid glasses very strongly. Therefore, the glasses are preferably free of this component. In order to increase the chemical resistance of the glass, Al₂O₃ is used, however, in certain embodiments in amounts of at least 1 wt-%. The content should, however, preferably not exceed 10 wt-%, more preferably 7 wt-% and particularly preferably 5 wt-%.

To affect the elasticity of the glasses particularly favorably, the opto-technical hybrid glasses preferably comprise at least one member selected from the group La₂O₃, Nb₂O₅, TiO₂ and BaO. These components have a hardening and stiffening effect on the glasses so that they increase the modulus of elasticity. Therefore, these components are preferably present in amounts of at least 7 wt-%, more preferably at least 15 wt-%, and more preferably at least 25 wt-% in the glasses of the present invention. In order not to decrease too much the elasticity, the content of these components should preferably not exceed an amount of 65 wt-%, more preferably of 55 wt-%, and particularly preferably of 45 wt-%. Moreover, these components should not be used in excess because they increase the crystallization tendency of the glass.

For the same reasons, in preferred embodiments, the content of BaO is restricted to at most 15 wt-% in the glass according to the present invention.

Preferred opto-technical hybrid glasses contain K₂O in quantities of at least 3.5 wt-%, particularly preferably at least 5 wt-%. The content of this component should preferably not exceed a value of 10 wt-%.

The opto-technical hybrid glasses contain one or more from said group in a proportion of at least 15 wt-%, more preferably at least 30 wt-%, and particularly preferably 45 wt-%. Particularly preferred glasses contain at least two representatives from this group. The glasses, however, should preferably contain not more than 65 wt-%, more preferably not more than 60 wt-%, and particularly preferably not more than 50 wt-% of these components.

According to the present invention even opto-technical hybrid glasses can be produced, which have a refractive index of n_{d}≧1.7 and preferably n_{d}≧1.8. Thereby the refractive index difference between the transparent oxide layer and the substrate layer is further reduced. By increasing the refractive index of the substrate, the refractive index difference between the glass and the ambient air is naturally increased. The thereby arising disadvantages can be taken into account by applying an optional anti-reflective coating. The skilled person is in principle aware of such anti-reflective coatings. In view of the usually very high refractive index of the transparent oxide layer, the refractive index of the opto-technical hybrid glass should preferably not exceed a value of n_{d}=2.4, more preferably of n_{d}=2.2 and more preferably of n_{d}=2.11.

For the above reasons, according to the present invention preferably opto-technical hybrid glasses are used that do not show too high dispersions. Therefore, the Abbe number of the opto-technical hybrid glasses is preferably v_{d}≧15, more preferably v_{d}≧18, more preferably v_{d}≧20, more preferably v_{d}≧24. Also opto-technical hybrid glasses with Abbe numbers of v_{d}≧26 can be used according to the present invention.

The opto-technical hybrid glasses of the present invention may belong to different glass classes. Preferred glass classes are lanthanum borates, alkaline earth borosilicates, lanthanum borosilicates, titanium silicates and alkaline earth titanium silicates. Hereinafter the particularly advantageous glasses are described.

The glasses of this invention are preferably free of lead for the above-described reasons. Preferred embodiments contain no arsenic, and in particular no antimony.

If it is said in this description that the opto-technical hybrid glasses are free of a component or do not contain a certain component, so it is thereby meant that this component may be present as an impurity in the glasses at the most. This means that it is not added in significant amounts. Not significant amounts are according to the present invention quantities of less than 100 ppm, preferably less than 50 ppm and most preferably less than 10 ppm.

### Lanthanum Borate Glasses

The preferred lanthanum borates contain lanthanum oxide in amounts of 25 to 50 wt-%. Lanthanum oxide is part of the high refractive lanthanum borate matrix. Present in a too small proportion in the glass, the preferred refractive index regions will not be achieved. If its content is too high, the crystallization risk increases due to lack of solubility of lanthanum in the borate matrix.

As solvent of lanthanum, boron oxide is used. It is preferably used in proportions of 7 to 41 wt-%, more preferably in proportions of 10 to 38 wt-%. Is the amount of boron oxide in the preferred glass is too small, the boron oxide content is not sufficient to dissolve the required amounts of lanthanum. Crystallization tendency is the result. If, however, an excessively large amount of boron oxide used, the desired high refractive indices are not achieved. In addition, a high boron oxide proportion increases the ion mobility in the glass, which increases again the crystallization tendency. Furthermore, high proportions of boron oxide in the glass increase the entry of the refractory material during manufacturing into the glass. This leads to inhomogeneity, scattering, heterogeneous nuclei and again crystallization.

The preferred lanthanum borates further comprise silicon dioxide in amounts from 0.5 to 11 wt-%, more preferably between 1 and 10 wt-%. This component increases the chemical resistance of the glass. If it is used in excessive amounts, however, it reduces the solubility of the lanthanum in the matrix, which can lead to crystallization.

Aluminum oxide also increases the chemical resistance of the glass. It is used in the lanthanum borates according to the present invention in amounts of preferably up to 5 wt-%. If this proportion is exceeded, however, the melting temperatures of the glass will be increased, which leads to increased energy consumption and reduced lifetime of the aggregates. Furthermore, an undesirably long glass is obtained. In embodiments of the present invention, the lanthanum borate glass is therefore free of aluminum oxide.

In order to obtain an optimal refractive index and optimal solubility of lanthanum in the matrix, it is advantageous when the content of lanthanum oxide and boron oxide is chosen so that the ratio of lanthanum oxide to boron oxide is set in a range from 0.5 to 7. More preferred is a ratio in a range from 0.7 to 5. If these preferred values are underrun, glasses with too low refractive index are obtained. If the values are exceeded, the glass tends to crystallize.

Similar considerations have led to choose the ratio of lanthanum oxide to the sum of the oxides silicon dioxide, boron oxide and aluminum oxide so that values of 0.5 to 3, preferably 0.5 to 5 are obtained.

It is preferred that the lanthanum borates, which can be used according to the present invention, contain lithium oxide in amounts of 0 to 2 wt-%, preferably 0 to 1.5 wt-%. This component is used for fine adjustment of the viscosity. In combination with boron oxide, this component can damage the production facilities strongly, leading to turbidity, heterogeneous nucleation and low lifetimes of the aggregates. Furthermore, lithium oxide leads to increased ion mobility, which in turn can lead to crystallization. Furthermore, chemical resistance of the glass is reduced. Therefore, preferred embodiments are free of lithium oxide.

The lanthanum borates used according to the present invention may include potassium oxide. Potassium oxide is used for fine adjustment of the viscosity. It is preferably contained in amounts of from 0 to 2 wt-%, more preferably in amounts of from 0 to 1.5 wt-% in the glass. Similar to lithium oxide, a too large proportion in the glass leads to increased ion mobility and low chemical resistance. Therefore, preferred embodiments are free of potassium oxide.

The lanthanum borates used according to the present invention may include sodium oxide. Sodium oxide is used for fine adjustment of the viscosity. It is preferably contained in amounts of from 0 to 2 wt-%, more preferably in amounts of from 0 to 1.5 wt-% in the glass. Similar to lithium oxide, a too large proportion in the glass leads to increased ion mobility and low chemical resistance. Therefore, preferred embodiments are free of sodium oxide.

From the previous paragraphs it is clear that the content of alkali oxides in the lanthanum borate glass has to be reduced in order to control crystallization. For this reason, the proportion of the alkali metal oxides lithium oxide, sodium oxide and potassium oxide is limited preferably to a content of in total at most 4 wt-%, more preferably at most 2 wt-%, most preferably at most 1 wt-%. Particular embodiments are even free of alkali metal oxides.

Embodiments of the lanthanum borates contain magnesium oxide. Preferably its content is up to 5 wt-%, more preferably up to 2 wt-%. Magnesium oxide is used to adjust the viscosity of the glass. If too much magnesium oxide is used, this increases the crystallization tendency of the glasses. Thus, preferred embodiments are free of magnesium oxide.

The lanthanum borates may include strontium oxide. This is then used in amounts of up to 5 wt-%, preferred embodiments contain at most 2 wt-%, in order to adjust the viscosity of the glass. If too much strontium oxide is used, too short glasses are obtained. Therefore, preferred embodiments are free of strontium oxide.

The lanthanum borates may also contain calcium oxide to adjust the temperature dependence of the viscosity. For this purpose, calcium oxide is used in amounts of up to 17 wt-%, preferred embodiments contain up to 10 wt-%. If too much calcium oxide is used, a too short glass is obtained.

The lanthanum borates may also include barium oxide. Barium oxide increases the refractive index of the glass and is used to adjust the temperature dependence of the viscosity. For this purpose, barium oxide is used in amounts of from 0 to 7 wt-%, preferably 0 to 5 wt-%. If, however, too much of barium oxide is used, a too short glass is obtained.

In order to optimally adjust the length of the glass, the proportion of the sum of the above-described alkaline earth metal oxides should preferably not exceed a value of 20 wt-%, more preferably are up to 10 wt-%. In preferred embodiments, the lanthanum borate glasses contain at least 2 wt-%, more preferably at least 4 wt-% alkaline earth metal oxides.

In order to optimally adjust the optical position of the lanthanum borate glasses, titanium oxide and/or zirconium oxide may be used. Thereby their content is in total up to 18 wt-%. In preferred embodiments, their content is about 3 to 16 wt-%. Particularly preferred are concentrations of 5 to 15 wt-%. In each case, the content of the individual components is preferably 0 to 10 wt-%, more preferably 0 to 9 wt-%. If these components are used in too large amounts, the crystallization tendency of the glasses is increased.

The glasses of the present invention may comprise yttrium oxide in amounts of from 0 to 20 wt-%, preferably 0 to 15, more preferably 0 to 10, and most preferably 0 to 5 wt-%. The same applies to the components of ytterbium oxide, gadolinium oxide and tantalum oxide. The component niobium oxide may be present in amounts of 0 to 20 wt-%, preferably 0 to 15 wt-%, more preferably 0 to 10 wt-% and more preferably 0 to 5 wt-%. The components listed in this paragraph are used to set the required high refractive indices according to the present invention. It must however be remembered that the quantities in which these components are used, should be limited because otherwise a reduced transmission is expected because of a shift of the UV edge. Furthermore, too large amounts result in crystal growth. Thereby preferred embodiments are entirely free from niobium oxide because this can be reduced in the float process. It has been found that the discussed oxides are used preferably in amounts of in total 0 to 36 wt-%, preferably 0 to 20 wt-%, more preferably 0 to 10 wt-% and most preferably from 0 to 5 wt-%. It should also be considered that these mentioned components are very expensive and for this reason the amount should be limited.

Particularly preferred lanthanum borate glasses according to this invention have the following composition in wt-%:

| | |
|---|---|
| La₂O₃ | 25 to 50 |
| B₂O₃ | 7 to 41 |
| SiO₂ | 0.5 to 11 |
| Al₂O₃ | 0 to 5 |
| La₂O₃/B₂O₃ | 0.5 to 7 |
| La₂O₃/(SiO₂ + B₂O₃ + Al₂O₃) | 0.5 to 3 |
| Li₂O | 0 to 2 |
| K₂O | 0 to 2 |
| Na₂O | 0 to 2 |
| Li₂O + Na₂O + K₂O | 0 to 4 |
| MgO | 0 to 5 |
| SrO | 0 to 5 |
| CaO | 0 to 17 |
| BaO | 0 to 7 |
| MgO + CaO + SrO + BaO | 0 to 20 |
| TiO₂ | 0 to 10 |
| ZrO₂ | 0 to 10 |
| TiO₂ + ZrO₂ | 0 to 18 |
| Y₂O₃ | 0 to 20 |
| Yb₂O₃ | 0 to 20 |
| Gd₂O₃ | 0 to 20 |
| Ta₂O₅ | 0 to 20 |
| Nb₂O₅ | 0 to 20 |
| Y₂O₃ + Yb₂O₃ + Gd₂O₃ + Ta₂O₅ + Nb₂O₅ | 0 to 36 |

In further preferred embodiments, the lanthanum borate glasses have the following composition in wt-%:

| | |
|---|---|
| La₂O₃ | 25 to 50 |
| B₂O₃ | 10 to 38 |
| SiO₂ | 1.0 to 10 |
| La₂O₃/B₂O₃ | 0.7 to 5 |
| La₂O₃/(SiO₂ + B₂O₃ + Al₂O₃) | 0.5 to 5 |
| Li₂O | 0 to 1.5 |
| K₂O | 0 to 1.5 |
| Na₂O | 0 to 1.5 |
| Li₂O + Na₂O + K₂O | 0 to 2 |
| MgO | 0 to 2 |
| SrO | 0 to 2 |
| CaO | 0 to 10 |
| BaO | 0 to 5 |
| MgO + CaO + SrO + BaO | 0 to 10 |
| TiO₂ | 0 to 9 |
| ZrO₂ | 0 to 9 |
| TiO₂ + ZrO₂ | 3 to 16 |
| Y₂O₃ | 0 to 15 |
| Yb₂O₃ | 0 to 15 |
| Gd₂O₃ | 0 to 15 |
| Ta₂O₅ | 0 to 15 |
| Nb₂O₅ | 0 to 15 |
| Y₂O₃ + Yb₂O₃ + Gd₂O₃ + Ta₂O₅ + Nb₂O₅ | 0 to 20 |

### Alkaline Earth Borosilicate Glasses

It has been found that even borosilicate glasses are suitable for being used according to the present invention. In a preferred embodiment the hybrid glass is an alkaline earth borosilicate glass.

As a glass former we used amongst others boron oxide, which also reduces the melting temperatures. It is preferably used in proportions of between 1 to 21 wt-%, more preferably in proportions of 3 to 20 wt-%, in particularly preferred embodiments it is present in amounts of 5 to 15 wt-%. If the amount of boron oxide in the preferred glass is too low, the viscosity of the glass is too high. However, if an excessively large amount of boron oxide is used, the desired high refractive indices are not achieved. In addition, the ion mobility is increased in the glass by a high boron oxide proportion, which in turn increases the crystallization tendency. Furthermore, high proportions of boron oxide in the glass increase the entry of the refractory material during manufacturing into the glass. This leads to inhomogeneity, scattering, heterogeneous nuclei and again crystallization.

The preferred alkaline earth borosilicate glasses further comprise silicon dioxide as a glass former in amounts of 25 to 65 wt-%, more preferably 30 to 60 wt-%, most preferably 35 to 55 wt-%. This component increases the chemical resistance and hardness of the glass. However, if it is used in excessive amounts, the high refractive indices are not reached and high melting temperatures complicate the manufacturing process.

Aluminum oxide also increases the chemical resistance of the glass. It is contained in alkaline earth borosilicate glasses according to the present invention in amounts of preferably up to 8 wt-%, more preferably up to 6 wt-%. If, however, this proportion is exceeded, then the melting temperatures of the glass are increased, which leads to increased energy consumption and reduced lifetimes of the aggregates. Furthermore, in this way an undesirably long glass is obtained. In embodiments of the invention, the alkaline earth borosilicate glass is therefore free of aluminum oxide.

Silicon dioxide and boron oxide are used for the formation of the glass matrix; it is advantageous when the content of silicon dioxide and boron oxide is selected so that the sum of silicon dioxide and boron oxide is in a value range of 35 to 66 wt-%. More preferred is a sum in a range of 40 to 64 wt-%. If these preferred values are underrun, glasses with a too low refractive index are obtained. Moreover, such a glass would have a tendency to crystallize and would have the characteristics of a long glass. For the same reasons, the sum of silicon dioxide, boron oxide and aluminum oxide (=sum of the glass formers) should be in a range of 41 to 68 wt-%, preferably 48 to 65 wt-%.

It is preferred that the alkaline earth metal borosilicates, which can be used according to the present invention, contain lithium oxide in amounts of 0 to 10 wt-%, preferably 0 to 8 wt-%. This component is used for fine adjustment of the viscosity. In combination with boron oxide, this component can strongly damage the production facilities, leading to turbidity, heterogeneous nucleation and low lifetimes of the aggregates. Furthermore, lithium oxide leads to increased ion mobility, which again leads to crystallization. In addition, the chemical resistance of the glass is reduced.

The alkaline earth metal borosilicates used according to the present invention may comprise potassium oxide. Potassium oxide is used for fine adjustment of the viscosity. It is preferably contained in amounts of from 0 to 10 wt-% in the glass. Similar to lithium oxide a too large proportion in the glass leads to increased ion mobility and low chemical resistance.

The alkaline earth metal borosilicates used according to the present invention may comprise sodium oxide. Sodium oxide is used for fine adjustment of the viscosity. It is preferably contained in the glass in amounts of from 0 to 10 wt-%. Similar to lithium oxide a too large proportion in the glass leads to increased ion mobility and low chemical resistance. Therefore, preferred embodiments are free of sodium oxide.

From the previous paragraphs it is clear that the content of alkali metal oxides in the alkaline earth borosilicate glass according to the present invention has to be limited in order to make fine adjustments to the viscosity. For this reason, the proportion of the alkali metal oxides lithium oxide, sodium oxide and potassium oxide is preferably limited to a content of at most 15 wt-%, more preferably at most 13 wt-%. In preferred embodiments, the glass is free of alkali metal oxides.

Embodiments of the alkaline earth metal borosilicates contain magnesium oxide. Preferably its content is up to 5 wt-%, more preferably up to 2 wt-%. Magnesium oxide is used to adjust the viscosity of the glass. If too much magnesium oxide is used, this increases the crystallization tendency of the glasses. Therefore, preferred embodiments are free of magnesium oxide.

The alkaline earth metal borosilicates may include strontium oxide. This is then present in amounts of up to 10 wt-%, preferred embodiments contain at most 9 wt-% in order to adjust the viscosity of the glass. If too much strontium oxide is used, too short glasses are obtained.

The alkaline earth metal borosilicates may include calcium oxide, to adjust the temperature dependence of the viscosity. For this purpose, calcium oxide is used in amounts of up to 10 wt-%, in preferred embodiments of up to 9 wt-%. If too much calcium oxide is used, too short glass is obtained.

The alkaline earth metal borosilicates may include barium oxide. Barium oxide increases the refractive index of the glass and is used to adjust the temperature dependence of the viscosity. For this purpose, barium oxide is used in amounts of 10 to 50 wt-%, preferably 11 to 48 wt-%, more preferably 15 to 45 wt-%. However, if too much of barium oxide is used, a too short glass is obtained. If too little is used, the refractive index of the resulting glass is too low, the glass is too long.

In order to optimally adjust the length of the glass, the proportion of the sum of the above-described alkaline earth metal oxides is preferably 10 to 52 wt-%, more preferably 13 to 52 wt-%, most preferably 15 to 45 wt-%.

Preferably, the proportion of the sum of the alkaline earth metal oxides and the glass formers altogether is at least 75 wt-%, more preferably at least 78 wt-%. In other embodiments, the proportion is 70-100 wt-%, more preferably 73 to 100 wt-%. It has turned out that thereby a suitable glass matrix for use according to the present invention can be provided.

To adjust the optical position of the alkaline earth metal borosilicate glass, titanium oxide and/or zirconium oxide may be used. In that, their content is in total up to 12 wt-%. In preferred embodiments its content is up to 10 wt-%, most preferably up to 8 wt-%. In that, the content of titanium oxide is preferably from 0 to 12 wt-%, the content of zirconium oxide preferably from 0 to 8 wt-%. If these components are used in too large amounts, the crystallization tendency of the glasses increases.

The glasses according to the present invention may contain yttrium oxide in amounts of from 0 to 5 wt-%. The same applies to the components of ytterbium oxide, gadolinium oxide, niobium oxide, lanthanum oxide and tantalum oxide. The components referred to in this paragraph are used to set the required high refractive indices according to the present invention. It has to be considered, however, that the amounts, in which these components are used, have to be limited, since otherwise a reduced transmission is expected due to a shift of the UV-edge. Furthermore, too large amounts lead to crystal growth. Here, preferred embodiments are entirely free of niobium oxide, because this can be reduced in the float process. It has turned out that the discussed oxides are preferably used in amounts of from 0 to 8 wt-%, preferably 0 to 3 wt-% in the alkaline earth metal borosilicate glass. It should also be considered that these mentioned components are very expensive and that also for this reason the amount should be limited.

Particularly preferred alkaline earth metal borosilicate glasses have the following composition, in wt-%:

| | |
|---|---|
| SiO₂ | 25 to 65 |
| B₂O₃ | 1 to 21 |
| Al₂O₃ | 0 to 8 |
| SiO₂ + B₂O₃ | 35 to 66 |
| SiO₂ + B₂O₃ + Al₂O₃ | 48 to 68 |
| Li₂O | 0 to 10 |
| K₂O | 0 to 10 |
| Na₂O | 0 to 10 |
| Li₂O + Na₂O + K₂O | 0 to 15 |
| MgO | 0 to 5 |
| CaO | 0 to 10 |
| SrO | 0 to 10 |
| BaO | 10 to 50 |
| MgO + CaO + SrO + BaO | 10 to 52 |
| MgO + CaO + SrO + BaO + SiO₂ + B₂O₃ + Al₂O₃ | 70 to 100 |
| TiO₂ | 0 to 12 |
| ZrO₂ | 0 to 8 |
| TiO₂ + ZrO₂ | 0 to 12 |
| La₂O₃ | 0 to 5 |
| Y₂O₃ | 0 to 5 |
| Yb₂O₃ | 0 to 5 |
| Gd₂O₃ | 0 to 5 |
| Ta₂O₅ | 0 to 5 |
| Nb₂O₅ | 0 to 5 |
| Y₂O₃ + Yb₂O₃ + Gd₂O₃ + Ta₂O₅ + Nb₂O₅ | 0 to 8 |

In further preferred embodiments, the alkaline earth metal borosilicate glasses have the following composition in wt-%:

| | |
|---|---|
| SiO₂ | 30 to 60 |
| B₂O₃ | 3 to 20 |
| Al₂O₃ | 0 to 6 |
| SiO₂ + B₂O₃ | 40 to 64 |
| SiO₂ + B₂O₃ + Al₂O₃ | 41 to 65 |
| Li₂O | 0 to 8 |
| K₂O | 0 to 10 |
| Na₂O | 0 to 10 |
| Li₂O + Na₂O + K₂O | 0 to 13 |
| MgO | 0 to 2 |
| CaO | 0 to 9 |
| SrO | 0 to 9 |
| BaO | 11 to 48 |
| MgO + CaO + SrO + BaO | 13 to 52 |
| GF + MO | 73 to 100 |
| TiO₂ | 0 to 12 |
| ZrO₂ | 0 to 8 |
| TiO₂ + ZrO₂ | 0 to 12 |
| La₂O₃ | 0 to 5 |
| Y₂O₃ | 0 to 5 |
| Yb₂O₃ | 0 to 5 |
| Gd₂O₃ | 0 to 5 |
| Ta₂O₅ | 0 to 5 |
| Nb₂O₅ | 0 to 5 |
| Y₂O₃ + Yb₂O₃ + Gd₂O₃ + Ta₂O₅ + Nb₂O₅ | 0 to 3 |

### Lanthanum Borosilicate Glasses

In another embodiment, the hybrid glass is a lanthanum borosilicate glass.

Boron oxide, which also reduces the melting temperatures, is used as a glass former and a solvent for the lanthanum. It is preferably used in proportions of 2 to 52 wt-%, more preferably in proportions of from 2 to 50 wt-%, in particularly preferred embodiments, it will be used in amounts of from 5 to 45 wt-%. If the proportion of boron oxide in the preferred glass is too low, the viscosity of the glass is too high. However, if an excessively large amount of boron oxide is used, the desired high refractive indices are not achieved. In addition, by a high proportion of boron oxide the ion mobility in the glass is increased, whereby the crystallization tendency is again increased. Furthermore, high proportions of boron oxide in the glass increase the entry of the refractory material into the glass during manufacturing. This leads to inhomogeneity, scattering, heterogeneous nuclei and again crystallization.

The preferred lanthanum borosilicate glasses further comprise silicon dioxide as a glass former in amounts of from 6 to 35 wt-%, more preferably from 9 to 33 wt-%, most preferably from 12 to 30 wt-%. This component increases the chemical resistance and hardness of the glass. If it is, however, used in excessive amounts, the high refractive index values are not achieved and high melting temperatures complicate the manufacturing process.

Aluminum oxide also increases the chemical resistance of the glass. It is contained in the lanthanum borosilicate glasses used according to the present invention in amounts of preferably up to 6 wt-%, more preferably to 4 wt-%, most preferably 2 wt-%. However, if this proportion is exceeded, the melting temperatures of the glass are increased, which leads to increased energy consumption and reduced lifetimes of the aggregates. Furthermore, thereby an undesirably long glass is obtained. In embodiments of the invention the lanthanum borosilicate glass is therefore free of aluminum oxide.

For the formation of the glass matrix silicon dioxide and boron oxide are used in addition to lanthanum oxide; it is advantageous when the content of silicon oxide and boron oxide is selected so that the sum of silicon dioxide and boron oxide are in a range from 20 to 60 wt-%. Further preferred is an amount in the range of 22 to 60 wt-%. If these preferred values are underrun, glasses with too low refractive index are obtained. Moreover, such a glass would tend to crystallize and have the characteristics of a long glass. For the same reasons, the sum of silicon dioxide, boron oxide and aluminum oxide (=sum of the glass former) should be in a range of 20 to 60 wt-%, preferably 22 to 60 wt-%.

The preferred lanthanum borosilicates contain lanthanum oxide in amounts of 3 to 25 wt-%, more preferably 5 to 25 wt-%, and most preferably 8 to 20 wt-%. Lanthanum oxide is part of the high refractive lanthanum borosilicate matrix. If it is present in a too small proportion in the glass, the preferred refractive index values will not be achieved. If its content is too high, the risk of crystallization increases due to lack of solubility of lanthanum in the borate matrix.

It is preferred that the lanthanum borosilicates, which can be used according to the present invention, contain lithium oxide in amounts of 0 to 2 wt-%. This component is used for fine adjustment of the viscosity. In combination with boron oxide, this component can strongly damage the production facilities, leading to turbidity, heterogeneous nucleation and low lifetimes of the aggregates. Furthermore, lithium oxide leads to increased ion mobility, which may again lead to crystallization. In addition, the chemical resistance of the glass is reduced. Therefore, preferred embodiments are free of lithium oxide.

The lanthanum borosilicates used according to the present invention may contain potassium oxide. Potassium oxide is used for fine adjustment of the viscosity. It is preferably contained in amounts of from 0 to 2 wt-% in the glass. Similar to lithium oxide a too large proportion in the glass leads to increased ion mobility and low chemical resistance. Therefore, preferred lanthanum borosilicate glasses are free from potassium oxide.

The lanthanum borosilicates used according to the present invention may include sodium oxide. Sodium oxide is used for fine adjustment of the viscosity. It is preferably contained in amounts of from 0 to 2 wt-% in the glass. Similar to lithium oxide too large proportions in the glass lead to increased ion mobility and low chemical resistance. Therefore, preferred embodiments are free of sodium oxide.

From the previous paragraphs it is clear that the content of alkali metal oxides in the lanthanum borosilicate glass according to the present invention should be limited, in order to make fine adjustments to the viscosity. For this reason, the proportion of the alkali metal oxides lithium oxide, sodium oxide and potassium oxide is preferably limited to an amount of at most 4 wt-%, more preferably 2 wt-%. Preferred embodiments are free of alkali metal oxides.

Embodiments of the lanthanum borosilicates contain magnesium oxide. Preferably its content is up to 5 wt-%, more preferably up to 3 wt-%. Magnesium oxide is used to adjust the viscosity of the glass. If too much magnesium oxide is used, this increases the crystallization tendency of the glasses. Therefore, preferred embodiments are free of magnesium oxide.

The lanthanum borosilicates may include strontium oxide. This is then used in amounts of up to 10 wt-%, to adjust the viscosity of the glass. If too much strontium oxide is used, too short glasses are obtained.

The lanthanum borosilicates may contain calcium oxide, to adjust the temperature dependence of the viscosity. For this purpose, calcium oxide is used in amounts of up to 35 wt-%. If too much calcium oxide is used, a too short glass is obtained.

The lanthanum borosilicates may also contain barium oxide. Barium oxide increases the refractive index of the glass and is used to adjust the temperature dependence of the viscosity. For this purpose, barium oxide is used in amounts of 0.5 to 50 wt-%, preferably 2 to 50 wt-%, more preferably 5 to 45 wt-%. However, if too much barium oxide is used, a too short glass is obtained. If too little is used, the refractive index of the resulting glasses is too low, the glass is too long.

To optimally adjust the length of the glass, the proportion of the sum of the above-described alkaline earth metal oxides should be preferably 24 to 50 wt-%, more preferred are 28 to 45 wt-%.

Preferably, the proportion of the sum of the alkaline earth metal oxides and the glass formers together is 40 to 97 wt-%, more preferably 44 to 97 wt-%. It is further preferred that the sum of the alkaline earth metal oxides, the glass formers and lanthanum oxide together is in a range of 65 to 100 wt-%, more preferably in a range of 68 to 100 wt-%. It has turned out that thereby a suitable glass matrix for use according to the present invention can be provided.

To adjust the optical position of the lanthanum borosilicate glass, titanium oxide and/or zirconium oxide may be used. In that, their content is in total up to 18 wt-%. In preferred embodiments, their content is up to 15 wt-%, most preferably up to 10 wt-%. In that, the content of titanium oxide is preferably 0 to 12 wt-%, more preferably 0 to 10 wt-%; the content of zirconium oxide is preferably 0 to 8 wt-%, more preferably 0 to 6 wt-%. If these components are used in too large amounts, the crystallization tendency of the glasses is increased.

The glasses according to the present invention may comprise yttrium oxide in amounts of 0 to 5 wt-%, preferably 0 to 3 wt-%. The same applies to the components of ytterbium oxide, gadolinium oxide and tantalum oxide. The components referred to in this paragraph are used to set the required high refractive indices according to the present invention. It has to be considered, however, that the amounts in which these components are used, have to be limited, since otherwise a reduced transmission is expected due to a shift of the UV-edge. Furthermore, too large amounts lead to crystal growth. According to the present invention the lanthanum borosilicate glass may contain niobium oxide in amounts of from 0 to 8 wt-%, preferably up to 5 wt-%. In that, preferred embodiments are entirely free from niobium oxide because this can be reduced in the float process. It has turned out that oxides discussed here are best used in amounts of together from 0 to 15 wt-%, preferably 0 to 8 wt-% in the lanthanum borosilicate glass. It should also be considered that these mentioned components are very expensive and for this reason the amount should be limited.

A particularly preferred lanthanum borosilicate glass of the present invention has the following composition in wt-%:

| | |
|---|---|
| SiO₂ | 6 to 35 |
| B₂O₃ | 2 to 52 |
| Al₂O₃ | 0 to 6 |
| SiO₂ + B₂O₃ | 20 to 60 |
| SiO₂ + B₂O₃ + Al₂O₃ | 20 to 60 |
| La₂O₃ | 3 to 25 |
| Li₂O | 0 to 2 |
| K₂O | 0 to 2 |
| Na₂O | 0 to 2 |
| Li₂O + Na₂O + K₂O | 0 to 4 |
| MgO | 0 to 5 |
| CaO | 0 to 35 |
| SrO | 0 to 10 |
| BaO | 0.5 to 50 |
| MgO + CaO + SrO + BaO | 24 to 50 |
| SiO₂ + B₂O₃ + Al₂O₃ + MgO + CaO + SrO + BaO | 40 to 97 |
| SiO₂ + B₂O₃ + Al₂O₃ + MgO + CaO + SrO + BaO + La₂O₃ | 65 to 100 |
| TiO₂ | 0 to 12 |
| ZrO₂ | 0 to 8 |
| TiO₂ + ZrO₂ | 0 to 18 |
| Y₂O₃ | 0 to 5 |
| Yb₂O₃ | 0 to 5 |
| Gd₂O₃ | 0 to 5 |
| Ta₂O₅ | 0 to 5 |
| Nb₂O₅ | 0 to 8 |
| Y₂O₃ + Yb₂O₃ + Gd₂O₃ + Ta₂O₅ + Nb₂O₅ | 0 to 15 |

In further preferred embodiments, the lanthanum borosilicate glass has the following composition in wt-%:

| | |
|---|---|
| SiO₂ | 9 to 33 |
| B₂O₃ | 2 to 50 |
| Al₂O₃ | 0 to 4 |
| SiO₂ + B₂O₃ | 22 to 60 |
| SiO₂ + B₂O₃ + Al₂O₃ | 22 to 60 |
| La₂O₃ | 3 to 25 |
| Li₂O | 0 to 2 |
| K₂O | 0 to 2 |
| Na₂O | 0 to 2 |
| Li₂O + Na₂O + K₂O | 0 to 2 |
| MgO | 0 to 3 |
| CaO | 0 to 35 |
| SrO | 0 to 10 |
| BaO | 0.5 to 50 |
| MgO + CaO + SrO + BaO | 24 to 50 |
| SiO₂ + B₂O₃ + Al₂O₃ + MgO + CaO + SrO + BaO | 44 to 97 |
| SiO₂ + B₂O₃ + Al₂O₃ + MgO + CaO + SrO + BaO + La₂O₃ | 68 to 100 |
| TiO₂ | 0 to 10 |
| ZrO₂ | 0 to 6 |
| Y₂O₃ | 0 to 3 |
| Yb₂O₃ | 0 to 3 |
| Gd₂O₃ | 0 to 3 |
| Ta₂O₅ | 0 to 3 |
| Nb₂O₅ | 0 to 8 |
| Y₂O₃ + Yb₂O₃ + Gd₂O₃ + Ta₂O₅ + Nb₂O₅ | 0 to 8 |

### Titanium Silicate Glasses

In other embodiments according to the present invention, the opto-technical hybrid glass is a silicate glass, in particular a titanium silicate glass.

In the titanium silicate glasses silicon dioxide is used as the main glass former in contents of 50 to 75 wt-%, more preferably 50 to 70 wt-%, most preferably 55 to 65 wt-%. This component increases the chemical resistance and hardness of the glass. If it is, however, used in too large amounts, the high refractive index values are not achieved and high melting temperatures complicate the manufacturing process.

As another glass former boron oxide is used, which also reduces the melting temperatures. It is preferably used in proportions of 0 to 10 wt-%, more preferably in proportions of 0 to 8 wt-%, in particularly preferred embodiments it is used in amounts of up to 7 wt-%. If the amount of boron oxide in the preferred glass is too low, the viscosity of the glass is too high. However, if an excessively large amount of boron oxide is used, the desired high refractive indices are not achieved. In addition, a high proportion of boron oxide increases the ion mobility in the glass, which increases again the crystallization tendency. Furthermore, high proportions of boron oxide in the glass increase the entry of the refractory material into the glass during manufacturing. This leads to inhomogeneity, scattering, heterogeneous nuclei and again crystallization.

Aluminum oxide also increases the chemical resistance and the abrasion resistance of the glass. It is contained in the titanium silicate glasses according to the present invention in amounts of preferably up to 10 wt-%, more preferably is to 9 wt-%, and most preferably up to 7 wt-%. If this proportion is exceeded, however, the melting temperatures of the glass will increase, which leads to increased energy consumption and reduced lifetimes of the aggregates. Furthermore, thereby an undesirably long glass is obtained.

Aluminum oxide and boron oxide are used besides silicon dioxide for the formation of the glass matrix; it is advantageous when the content of aluminum oxide and boron oxide is selected so that the sum of aluminum oxide and boron oxide in a range of 0 to 15 wt-%. More preferred is a sum within a range of 0 to 12 wt-%, particularly preferred 0 to 10 wt-%. If these values are exceeded, the crystallization stability of the glasses is adversely affected. However, in order to ensure sufficient stability the sum of silicon dioxide, boron oxide and aluminum oxide (=sum of the glass formers) should be in a range from 50 to 75 wt-%, preferably from 52 to 73 wt-%, most preferably 55 to 70 wt-%. The proportion of silicon dioxide with regard to the sum of the glass formers should be 0.8 to 1.

Titanium dioxide is used in the glass to increase the refractive index and the dispersion. Its content should be 5 to 25 wt-%, preferably 7 to 23 wt-%, and most preferably 9 to 20 wt-%. For adjustment of the optical position furthermore zirconium oxide is used in amounts of 0 to 5, preferably from 0 to 3 wt-%. If these values are underrun, the desired optical position cannot be achieved. If the values are exceeded, however, the crystallization tendency of the glasses is increased. The sum of these two components should be from 5 to 25 wt-%, preferably from 7 to 22 wt-%, and most preferably from 10 to 20 wt-%. Ideally, the sum of titanium oxide, zirconium oxide and glass formers together should be 70 to 85 wt-%, more preferably 73 to 83 wt-%, and most preferably at least 75 wt-%.

It is preferable that the titanium silicates, which may be used according to the invention, contain lithium oxide in amounts of 0 to 5 wt-%, preferably 0 to 3 wt-%. This component is used for fine adjustment of the viscosity. In combination with boron oxide, this component can strongly damage the production facilities, leading to turbidity, heterogeneous nucleation and low lifetimes of the aggregates. Furthermore, lithium oxide leads to increased ion mobility, which may again lead to crystallization. In addition, the chemical resistance of the glass is reduced. Therefore, preferred embodiments are free of lithium oxide.

The titanium silicates used according to the present invention may include potassium oxide. Potassium oxide is used to adjust the dependence of the viscosity of temperature changes. It is preferably contained in the glass in amounts of 0 to 25 wt-%, more preferably 3 to 23 wt-%. Similar to lithium oxide a too large proportion in the glass leads to increased ion mobility and low chemical resistance. If a too small amount is selected, the viscosity of the glass is too high.

The titanium silicates used according to the present invention may include sodium oxide. Sodium oxide is used to adjust the temperature viscosity profile. It is preferably contained in amounts of 0 to 15 wt-% in the glass. Similar to lithium oxide, a too large proportion in the glass leads to increased ion mobility and low chemical resistance. Preferred embodiments are free of lithium oxide.

From the previous paragraphs it is clear that the content of alkali metal oxides in the titanium silicate glass according to the present invention has to be limited in order to adjust the viscosity and the temperature dependency of the viscosity. For this reason, the proportion of the alkali metal oxides lithium oxide, sodium oxide and potassium oxide is preferably restricted to a level of 15 to 25 wt-%, more preferably 17 to 25 wt-% and most preferably 18 to 22. In preferred embodiments this glass contains, with the exception of potassium oxide, no alkali metal oxides.

In order to optimally adjust the length of the glass, the proportion of the sum of the alkaline earth metal oxides magnesium oxide, calcium oxide, strontium oxide and barium oxide should be preferably 0 to 5 wt-%, more preferably 0 to 3 wt-%, most preferably the glass is free of alkaline earth metal oxides.

A particularly preferred titanium silicate glass has following composition in wt-%

| | |
|---|---|
| SiO₂ | 50 to 75 |
| B₂O₃ | 0 to 10 |
| Al₂O₃ | 0 to 10 |
| B₂O₃ + Al₂O₃ | 0 to 15 |
| SiO₂ + B₂O₃ + Al₂O₃ | 50 to 75 |
| SiO₂/(SiO₂ + B₂O₃ + Al₂O₃) | 0.8 to 1 |
| TiO₂ | 5 to 25 |
| ZrO₂ | 0 to 5 |
| TiO₂ + ZrO₂ | 5 to 25 |
| GF + TiO₂ + ZrO₂ | 70 to 85 |
| Li₂O | 0 to 5 |
| Na₂O | 0 to 15 |
| K₂O | 0 to 25 |
| Li₂O + Na₂O + K₂O | 15 to 25 |
| MgO + CaO + SrO + BaO | 0 to 5 |

In further preferred embodiments, the titanium silicate glass has following composition in wt-%:

| | |
|---|---|
| SiO₂ | 50 to 70 |
| B₂O₃ | 0 to 8 |
| Al₂O₃ | 0 to 9 |
| B₂O₃ + Al₂O₃ | 0 to 15 |
| SiO₂ + B₂O₃ + Al₂O₃ | 52 to 73 |
| SiO₂/(SiO₂ + B₂O₃ + Al₂O₃) | 0.8 to 1 |
| TiO₂ | 7 to 22 |
| ZrO₂ | 0 to 3 |
| TiO₂ + ZrO₂ | 7 to 22 |
| GF + TiO₂ + ZrO₂ | 73 to 83 |
| Li₂O | 0 to 3 |
| Na₂O | 0 to 15 |
| K₂O | 3 to 23 |
| Li₂O + Na₂O + K₂O | 17 to 25 |
| MgO + CaO + SrO + BaO | 0 to 3 |

### Alkaline Earth Metal Titanium Silicate Glasses

In another preferred embodiment, the glass used according to the present invention is a silicate glass of the type alkaline earth metal titanium silicate glass.

In the alkaline earth metal titanium silicate glasses, silicon dioxide is used as main glass former in contents of 20 to 50 wt-%, more preferably 25 to 50 wt-%, most preferably up to 47 wt-%. This component increases the chemical resistance and hardness of the glass. However, if it is used in excessive amounts, the high refractive indices will not be reached and high melting temperatures complicate the manufacturing process.

As another glass former boron oxide is used, which also reduces the melting temperatures. It is preferably used in proportions of 0 to 10 wt-%, more preferably in proportions of 0 to 8 wt-%, in particularly preferred embodiments, it is used in amounts of up to 7 wt-%. If the amount of boron oxide in the preferred glass is too low, the viscosity of the glass is too high. However, if an excessively large amount of boron oxide is used, the desired high refractive indices are not achieved. In addition, the ion mobility in the glass is increased by a high proportion of boron oxide, which increases again the crystallization tendency. Furthermore, high proportions of boron oxide in the glass increase the entry of the refractory material into the glass during manufacturing. This leads to inhomogeneity, scattering, heterogeneous nuclei and crystallization again.

Aluminum oxide also increases the chemical resistance of the glass. In alkaline earth metal titanium silicate glasses according to the present invention it is contained in amounts of preferably up to 5 wt-%, more preferably to 3 wt-%. However, if this proportion is exceeded, the melting temperatures of the glass are increased, which leads to increased energy consumption and reduced lifetimes of the aggregates. Furthermore, thereby an undesirably long glass is obtained. In embodiments of the invention, the alkaline earth metal titanium silicate glass is therefore free of aluminum oxide.

For the formation of the glass matrix among others aluminum oxide and boron oxide are used; it is advantageous if the content of these components is selected so that the sum of aluminum oxide and boron oxide in a range from 0 to 10 wt-%. More preferred is a sum within a range of 0 to 8 wt-%, most preferred are up to 7 wt-%. If this content is chosen too large, the glass tends to crystallization.

The sum of silicon dioxide, boron oxide and aluminum oxide (=sum of the glass formers) should be in a range from 20 to 55 wt-%, preferably from 25 to 55 wt-%, most preferably up to 30 wt-%. The ratio of silicon dioxide to the sum of the glass formers should be 0.8 to 1. Thereby, a glass with the required resistance is obtained.

It is preferred that the alkaline earth metal titanium silicates, which can be used according to the present invention, contain lithium oxide in amounts of 0 to 5 wt-%, preferably 0 to 2 wt-%. This component is used for fine adjustment of the viscosity. In combination with boron oxide it can strongly damage the production facilities, leading to turbidity, heterogeneous nucleation and low lifetimes of the aggregates. Furthermore, lithium oxide leads to increased ion mobility, which in turn can lead to crystallization. In addition, the chemical resistance of the glass is reduced. Therefore, preferred embodiments are free of lithium oxide.

The alkaline earth metal titanium silicates used according to the present invention may contain potassium oxide. Potassium oxide is used for fine adjustment of the viscosity. It is preferably contained in amounts of 0 to 10 wt-%, more preferably 0.5 to 8 wt-% in the glass. Similar to lithium oxide a too large proportion in the glass leads to increased ion mobility and low chemical resistance.

The alkaline earth metal titanium silicates used according to the present invention may include sodium oxide. Sodium oxide is used for fine adjustment of the viscosity. It is preferably contained in amounts of 0 to 15 wt-%, more preferably 3 to 13 wt-% in the glass. Similar to lithium oxide a too large proportion in the glass leads to increased ion mobility and low chemical resistance. Therefore, preferred embodiments are even free of sodium oxide.

From the previous paragraphs it is clear that the content of alkali metal oxides in the alkaline earth metal titanium silicate glass has to be limited in order to make fine adjustments of the viscosity. For this reason, the proportion of the alkali metal oxides lithium oxide, sodium oxide and potassium oxide is preferably limited to a content of 8 to 25 wt-%, more preferably 10 to 22 wt-%. In preferred embodiments their content is at least 13 wt-%. Preferably, this glass contains no alkali metal oxides besides potassium oxide.

Embodiments of the alkaline earth metal titanium silicates contain magnesium oxide. Preferably its content is up to 5 wt-%, more preferably up to 3 wt-%. Magnesium oxide is used to adjust the viscosity of the glass. If too much magnesium oxide is used, this increases the crystallization tendency of the glasses. Therefore, preferred embodiments are free of magnesium oxide.

The alkaline earth metal titanium silicates may comprise strontium oxide. This is then used in amounts of up to 5 wt-%, preferred embodiments contain at most 3 wt-% in order to adjust the viscosity of the glass. If too much strontium oxide is used, too short glasses are obtained.

The alkaline earth metal titanium silicates may contain calcium oxide, in order to adjust the temperature dependence of the viscosity. For this purpose calcium oxide is used in amounts of up to 5 wt-%, preferred embodiments contain up to 3 wt-%. If too much calcium oxide is used, a too short glass is obtained.

The alkaline earth metal titanium silicates may comprise barium oxide. Barium oxide increases the refractive index of the glass and is used to adjust the temperature dependence of the viscosity. For this purpose, barium oxide is used in amounts of 4 to 20 wt-%, preferably 4 to 18 wt-%. However, if too much barium oxide is used, a too short glass is obtained. If too little is used, the refractive index of the resulting glass is too low, the glass is too long.

In order to optimally adjust the length of the glass, the proportion of the sum of the above-described alkaline earth metal oxides should preferably have a value of 4 to 25 wt-%.

To adjust the optical position of the alkaline earth metal titanium silicate glass, titanium oxide and zirconium oxide are used. In that, their content is in total 15 to 35 wt-%. In preferred embodiments their content is 18 to 32 wt-%. In that, the content of titanium oxide is preferably 12 to 35 wt-%, more preferably 15 to 30 wt-%; the content of zirconium oxide is preferably 0 to 8 wt-%, more preferably 0 to 5 wt-%. If these components are used in too large amounts, the crystallization tendency of the glasses increases. To prevent this, the sum of the proportions of titanium dioxide, zirconium oxide and the glass formers should have values of 50 to 80 wt-%, preferably 52 to 77 wt-%.

Preferably the proportion of the sum of titanium oxide, zirconium oxide, the alkaline earth metal oxides and the glass formers together is 65 to 92 wt-%, more preferably 65 to 88 wt-%. In other embodiments, this proportion is at least 68 wt-%, more preferably at least 70 wt-%, and most preferably at least 85 weight-%. It has turned out that thereby a suitable glass matrix can be provided for use according to the present invention.

The glasses according to the present invention may contain yttrium oxide, ytterbium oxide, gadolinium oxide, niobium oxide and tantalum oxide in proportions of together 0 to 20 wt-%, preferably 0 to 15 wt-%, more preferably 0 to 12 wt-%, and most preferably 0 to 10 wt-%. The components referred to in this paragraph are used to set the needed optical position according to the present invention. It has to be considered however, that the amounts, in which these components are used, have to be limited, since otherwise a reduced transmission is expected due to a shift of the UV-edge. Furthermore, too large amounts lead to crystal growth. In that, preferred embodiments are entirely free from niobium oxide, because this can be reduced in the float process.

Particularly preferred alkaline earth metal titanium silicate glasses have the following composition in wt-%:

| | |
|---|---|
| SiO₂ | 20 to 50 |
| B₂O₃ | 0 to 10 |
| Al₂O₃ | 0 to 5 |
| B₂O₃ + Al₂O₃ | 0 to 10 |
| SiO₂ + B₂O₃ + Al₂O₃ | 20 to 55 |
| SiO₂/(SiO₂ + B₂O₃ + Al₂O₃) | 0.8 to 1 |
| TiO₂ | 12 to 35 |
| ZrO₂ | 0 to 8 |
| TiO₂ + ZrO₂ | 15 to 35 |
| SiO₂ + B₂O₃ + Al₂O₃ + TiO₂ + ZrO₂ | 50 to 80 |
| Li₂O | 0 to 5 |
| Na₂O | 0 to 15 |
| K₂O | 0 to 10 |
| Li₂O + Na₂O + K₂O | 8 to 25 |
| MgO | 0 to 5 |
| CaO | 0 to 5 |
| SrO | 0 to 5 |
| BaO | 4 to 20 |
| MgO + CaO + SrO + BaO | 4 to 25 |
| SiO₂ + B₂O₃ + Al₂O₃ + MgO + CaO + SrO + BaO + TiO₂ + | 65 to 92 |
| ZrO₂ | |
| Y₂O₃ + Yb₂O₃ + Gd₂O₃ + Ta₂O₅ + Nb₂O₅ | 0 to 20 |

In further preferred embodiments alkaline earth metal titanium silicate glass the composition in wt-%:

| | |
|---|---|
| SiO₂ | 25 to 50 |
| B₂O₃ | 0 to 8 |
| Al₂O₃ | 0 to 3 |
| B₂O₃ + Al₂O₃ | 0 to 8 |
| SiO₂ + B₂O₃ + Al₂O₃ | 25 to 55 |
| SiO₂/(SiO₂ + B₂O₃ + Al₂O₃) | 0.8 to 1 |
| TiO₂ | 15 to 30 |
| ZrO₂ | 0 to 5 |
| TiO₂ + ZrO₂ | 18 to 32 |
| SiO₂ + B₂O₃ + Al₂O₃ + TiO₂ + ZrO₂ | 52 to 77 |
| Li₂O | 0 to 2 |
| Na₂O | 3 to 13 |
| K₂O | 0.5 to 8 |
| Li₂O + Na₂O + K₂O | 10 to 22 |
| MgO | 0 to 3 |
| CaO | 0 to 3 |
| SrO | 0 to 3 |
| BaO | 4 to 18 |
| MgO + CaO + SrO + BaO | 4 to 25 |
| SiO₂ + B₂O₃ + Al₂O₃ + MgO + CaO + SrO + BaO + TiO₂ + | 65 to 88 |
| ZrO₂ | |
| Y₂O₃ + Yb₂O₃ + Gd₂O₃ + Ta₂O₅ + Nb₂O₅ | 0 to 15 |

By different ratios of the components of the basic glass matrices and the supplementary added highly refractive components it is possible to set glasses with refractive indices of a wide range in all three glass families. In this way, the accessible areas of the glass families encompass refractive indices between >1.6 and 1.85. Preferably, the glasses have refractive indices of n_{d}>1.6, more preferably n_{d}>1.7 and most preferably n_{d}>1.8. In that, lanthanum borates represent optical regions of lesser dispersion, while the titanium silicates have extremely high dispersions. Glasses with borosilicate matrix are here in the moderate middle.

All these glasses are, except for unavoidable impurities, preferably free of highly redox-active polyvalent components such as the oxides of lead, arsenic and antimony because of the intended fitness for flat glass processes, especially float glass processes. These components would otherwise lead to discoloration in the glass during the flat glass process, which would undermine the aim according to the present invention of greater efficiency in terms of light output. Hereby the allowed refining agents are restricted to the physical refining support. Therefore, preferably F, SnO, NaCl are used as refining agents in amounts of up to 1 wt-%. Less preferred embodiments of not-float flat glass processes such as the drawing process, the downdraw process or also overflow fusion processes, however, may contain the common redox refining agents arsenic oxide and antimony oxide necessary for the refining process in conventional amounts (up to 1 wt-%).

For the same reason, the opto-technical hybrid glasses do also preferably not contain, except for unavoidable impurities, the weaker redox-active oxides of niobium and tungsten. It is most preferable that the optical-technical hybrid glasses are free of redox-active components.

It is preferred according to the present invention that the hybrid glasses are free of zinc oxide except for unavoidable impurities. Furthermore, it is preferred that the hybrid glasses are free of bismuth oxide except for unavoidable impurities.

The glasses according to the present invention are thus ecologically friendly optical glasses for the application areas of lighting and display.

Further preferred embodiments for the float process, however, are additionally, except for unavoidable impurities, free of weaker redox-active components, i.e. the oxides of tungsten and niobium. For niobium, however, this does not apply in the glasses of the lanthanum borate family, since in this matrix, the niobium oxide has a significantly lower redox potential and can be used up to a content of 20 wt-%. The use of these components leads to formation of colored components due to redox reactions with the tin float bath, which are contrary to the object of high transmission already of the bulk glasses.

Comparably, bismuth oxide is reduced to elemental bismuth, which elicits transmission-reducing scattering effects and additionally can serve as a nucleus for crystallization. Further preferred embodiments are therefore free of bismuth oxide except for unavoidable impurities.

Also embodiments preferred with regard to the float process are except for unavoidable impurities free of zinc oxide, which results in contact with the float bath to surface crystallization in the hot forming process.

According to the present invention, a flat glass, which can serve as a substrate for the layer composite assembly, is produced from the above described glasses. This means that it serves as a basis for the construction of the transparent layer composite assembly. In that, it is advantageous that the glass can withstand high temperatures without damage. The processing temperature of the conductive transparent oxide will usually be so high that the organic semiconductor would decompose. Therefore, in the manufacturing process of the layer composite assembly initially the transparent oxide layer is applied to the substrate and only then the organic semiconductor is applied.

The glasses according to the present invention are optionally chemically preloaded to prevent breaks under mechanical stress. For this purpose it is preferred that all glasses contain aluminum oxide. Aluminum oxide positively modifies the network structure towards increased ion mobility (for the exchange), but without (as for example the alkali metal oxides and boron oxide) thereby significantly increasing the crystallization tendency.

The transparent oxide layer in the transparent layer composite assembly of the present invention is conductive according to the present invention and preferably comprises ITO. ITO has proven itself as a material for transparent oxide layers. Also according to the present invention is the use of low-molecular layers of graphene, a highly conductive transparent material.

According to the present invention the refractive index of said opto-technical hybrid glass is adapted to the refractive index of the oxide layer. In that, the difference between the refractive indices of the two layers is preferably at most 0.5, more preferably at most 0.4 and especially preferably at most 0.3. This embodiment is preferred because the transparent oxide layer is the layer in the transparent layer composite assembly which usually follows the substrate layer in the output direction of the emitted light. For this reason, the substrate is a so-called “superstrate”.

The semiconductor layer in the transparent layer composite assembly of this invention preferably comprises an organic semiconductor. These can be divided on basis of their molecular masses in conjugated molecules and conjugated polymers. In this way, Organic LEDs are classified based on conjugated molecules (SOLED or SMOLED) and based on conjugated polymers (PLEDs). The organic semiconductor used according to the present invention is preferably selected from the group of conjugated polymers, consisting of heterocyclic polymers, in particular polythiophenes, polyparaphenylene, polypyrrole, polyaniline, and hydrocarbon chains, in particular polyacetylene, polysulfurnitrides, in each case also substituted possible. According to the present invention, derivatives of poly (p-phenylene vinylene) (PPV) or at more efficient new developments organometallic complexes (triplet emitter) may be used as dyes. In alternative embodiments, the semiconductor is not transparent.

A light emitting diode or a corresponding solar module prepared by using the layer composite assembly has, in addition to the semiconductor layer, the transparent oxide layer and the substrate layer, i.e. the layer composite assembly of the present invention, a cathode layer which comprises a metallic or alloy cathode. The metallic cathodes are preferably selected from the group consisting of calcium, aluminum, barium, ruthenium, while the alloyed cathodes are preferably selected from the group consisting of magnesium-silver alloy, and alloys of the components of metallic cathodes.

According to the present invention is also the use of the transparent layer composite assembly as a component of a light emitting diode, preferably OLED, more preferably PLED.

According to the present invention is also a method for manufacturing a transparent layer composite assembly according to the present invention, which comprises the following steps:

Preparation of the Substrate in a Flat Glass Process

Joining the substrate with the other layers to form a layer composite assembly.

The preparation of the substrate in a flat glass process is preferably performed in a continuous melting process: the mixture prepared according to the synthesis procedure is batchwise (in portions) supplied to a conventional melting furnace, and there heated in the melting region until a melt flow of sufficiently low viscosity for the subsequent process is reached. Usually, this is accomplished at temperatures that are correlating to viscosities below 10³ dPas by the temperature-viscosity curve of each glass type.

During the further passage through the aggregate the formation of convection rolls for homogenizing the raw melt flow is preferably achieved at these viscosities. The homogenization can be done also by blowing inert or redox stabilizing gases (nitrogen, helium or oxygen) or by mechanical stirring. At further lowered viscosities (approximately from 10^{2.5} dPas) the refining process can initiate, which releases the crude melt from the gas load generated during melting either by chemical or by physical refining processes and that results in bubble-free glass. This refined and homogenized glass flux is then preferably supplied to one of the various possible HFG methods (drawing, rolling, floating, downdraw, overflow fusion) approximately at viscosities around VA (10⁴ dPas). At this, it has to be noted that at the desired float process, the use of a classical redox refining is prohibited. The resultant continuous ribbon of glass of desired width and thickness is isolated into the desired length of the plates/discs, preferably after passing through a cooling section in order to prevent stress fractures.

The float process makes it possible to produce substrates for layer composite assemblies according to the present invention economically and in the required scale. In that, two aspects have a particularly positive effect in the float process: the dead-spot-free construction of the HFG-portion of a float tank leads to significantly lower demands that are made on the devitrification stability of the material and to an expanded number of types of glass for which the flat glass process is accessible, in this case the highly refractive hybrid glasses, which are in comparison with standard technical glasses more crystallization-sensitive. “Dead-spot-free” means in this case that no partial portions of the melt flux stay significantly longer in geometrically little flown-through corners (dead volume or dead spots) at HFG-viscosities at which nucleation and crystal growth take place at an increased risk.

The second particularly positive aspect of floating is the lying of the glass ribbon on the tin bath uninfluenced by gravity, which prevents the unwanted deformation after the nozzle, particularly cockling, etc. (of course not the desired targeted wide flowing of the glass ribbon). Thus, the effective yield can be increased by decreasing geometric exclusion significantly compared to draw and rolling processes without early tack-free layer.

Based on the new class of hybrid glasses presented here, a highly transmissive material composite assembly was created by refractive index matching to the transparent oxide layer, here preferably the ITO layer, contributing by increased light output to efficiency enhancement of organic light emitting diodes, and thus to an optimized generation of OLEDs and solar modules.

By the hybrid glasses according to the present invention, such adjustment of the crystallization stability and of the viscosity-temperature-profile was realized in addition to a sufficient redox stability, that the preparation of these optical glasses, which are necessarily highly refractive for a highly transparent layer composite assembly, is enabled in a flat-glass process, here in particular the float process.

The highly-refractive glasses according to the present invention are thus suitable to be used in their geometry, obtained by production in a flat glass process, preferably in a float glass process, as a flat, thin superstrate, in order to produce a highly transparent layer composite assembly by depositing transparent conductive oxide layers thereon, in particular, ITO layers or alternatively non-oxide graphene layers, for manufacturing efficiency optimized OLEDs. The layer thickness of the substrate is smaller than 2 mm, preferably less than 1.5 mm, more preferably it is in the range of 0.7 to 1.1 mm.

If nothing else is stated in this description, terms like “free from”, “not included” and similar terms mean in each case that the corresponding component was not added purposefully to the glass; it is meant that said component is contained at most as an impurity in the glass.

In preferred embodiments, the glasses described consist of at least 90 wt-%, more preferably 95 wt-%, and most preferably 98 wt-% of the components, which are stated herein as part of the respective glasses.

### EXAMPLES

Tables 2-6 contain 45 embodiments, in the preferred composition ranges. The glasses according to the present invention are produced as follows:

Due to the cost- and capacity-intensive glass exchange in a conventional flat glass aggregate only some of the examples were produced in a large volume flat glass aggregate. Instead, the embodiments have been melted in lab volume in Platinum1Iridium and silica crucibles and subsequently material-specific parameters have been recorded, which provide information about the manufacturability in a flat glass process.

In addition to the viscosity-temperature curve, the upper devitrification limit (OEG, carrier plate method, rising temperature control) was acquired and the redox behavior in terms of elemental tin was characterized electrochemically. The glasses according to the present invention exhibit thus OEGs at temperatures, which are at least 20K, preferably 50K, more preferably 100K below the HFG-temperatures, i.e. at viscosities above the respective process-specific HFG-viscosity. In that, the glasses (apart from unavoidable impurities free of polyvalent compounds and zinc oxide) preferred for a float process according to the present invention exhibit in the electrochemical characterization no signs of a redox-sensitive reaction with the tin bath.

For production in a conventional flat glass aggregate, the raw materials for the oxides, preferably the oxides themselves and/or carbonates and/or fluorides, are weighed, one or more process-adjusted refining agents are added and subsequently mixed well. The glass mixture is melted glass-type-dependent at temperatures, which correspond to viscosities of about 10³ dPas in a continuous melting aggregate and often homogenized via the setting of convection rolls, then at temperatures corresponding to viscosities of about 10^{2.5} dPas refined and finally homogenized. At a lowered flow temperature, corresponding to viscosities of about 10⁴ dPas (processing temperature VA), the glass is supplied to the respective HFG-process and processed to the desired dimensions.

TABLE 1
Melting example for 100 kg of calculated glass

| Oxide | wt-% | Raw material | Weighed portion (kg) |
|---|---|---|---|
| SiO₂ | 45 | SiO₂ | 44.97 |
| Li₂O | 2 | Li₂CO₃ | 4.96 |
| Na₂O | 3 | Na₂CO₃ | 5.12 |
| K₂O | 10 | K₂CO₃ | 14.70 |
| MgO | 5 | MgCO₃ | 11.58 |
| BaO | 18 | BaCO₃ | 23.12 |
| TiO₂ | 15 | TiO₂ | 15.06 |
| ZrO₂ | 2 | ZrO₂ | 1.99 |
| NaCl | 0.2 | NaCl | 0.19 |
| Sum | 100.2 | | 121.69 |

The properties of the resulting glass are shown in Table 6, Example 36.

TABLE 2
Melting examples lanthanum borates (in wt-%)

| | Example | | | | | | | |
|---|---|---|---|---|---|---|---|---|
| | 1 | 2 | 3 | 4 | 5 | 6 | 8 | 9 |
| SiO₂ | 7 | 4 | 0.5 | 4 | 1 | 11 | 10 | 8 |
| B₂O₃ | 41 | 34 | 32 | 38 | 17 | 7 | 14 | 10 |
| Al₂O₃ | | 1 | | | | | | |
| Li₂O | | | | 1 | | | | |
| Na₂O | | | | | | | | 1 |
| K₂O | | | 1.5 | | | | | |
| MgO | | | 2 | | | | 5 | |
| CaO | 10 | | | 5 | | | 10 | 5 |
| BaO | | 8 | | | | | | |
| SrO | | 2 | | 1 | | | | |
| TiO₂ | | | | 2 | | | 9 | |
| ZrO₂ | 3 | 5 | 4 | 5 | 9 | 8 | 7 | 5 |
| La₂O₃ | 39 | 41 | 45 | 42 | 50 | 47 | 25 | 40 |
| Y₂O₃ | | 2 | 8 | | | | | 4 |
| Yb₂O₃ | | | | | | 5 | | |
| Gd₂O₃ | | | 7 | | | 10 | | 9 |
| Ta₂O₅ | | 2 | | | 8 | 12 | | 16 |
| Nb₂O₅ | | | | 2 | 15 | | 20 | 2 |
| Sum | 100 | 100 | 100 | 100 | 100 | 100 | 100 | 100 |
| nd | 1.70 | 1.74 | 1.75 | 1.74 | 1.88 | 1.88 | 1.89 | 1.88 |
| vd | 55 | 52 | 53 | 51 | 38 | 41 | 31 | 41 |
| Tg [° C.] | 662 | 639 | 641 | 637 | 680 | 719 | 649 | 700 |
| CTE_{20/300} [ppm/K] | 7.0 | 6.7 | 6.8 | 6.8 | 7.3 | 7.7 | 8.3 | 8.6 |
| specific density | 3.6 | 4.0 | 4.1 | 4.1 | 4.8 | 5.5 | 4.0 | 5.4 |
| [g/cm³] | | | | | | | | |
| τ_{i 2 mm 420 nm} [%] | 99.8 | 99.8 | 99.7 | 99.8 | 99.4 | 99.2 | 98.8 | 99.4 |

TABLE 3
Melting examples alkaline earth metal borosilicates (in wt-%)

| | Example | | | | | | | | |
|---|---|---|---|---|---|---|---|---|---|
| | 10 | 11 | 12 | 13 | 14 | 15 | 16 | 17 | 18 |
| SiO₂ | 33 | 25 | 30 | 43 | 31 | 60 | 54 | 50 | 38 |
| B₂O₃ | 11 | 21 | 20 | 15 | 10 | 1 | 7 | 9 | 5 |
| Al₂O₃ | 8 | 6 | | 4 | 1 | | 1 | 2 | |
| Li₂O | | | | 6 | 0.5 | | | | |
| Na₂O | | | | 3 | 0.5 | 3 | 10 | 5 | 7 |
| K₂O | | | | | | 10 | 4 | 6 | 1 |
| MgO | | 2 | | 3 | 5 | 5 | 1 | | 5 |
| CaO | | | | | | | | 1 | 9 |
| BaO | 48 | 45 | 50 | 25 | 41 | 19 | 10 | 15 | 24 |
| SrO | | | | 1 | 1 | | 3 | | |
| TiO₂ | | | | | 1 | | 9 | 12 | 7 |
| ZrO₂ | | | | | 8 | | | | 4 |
| La₂O₃ | | 1 | | | | | | | |
| Y₂O₃ | | | | | | 1 | | | |
| Yb₂O₃ | | | | | | | 1 | | |
| Gd₂O₃ | | | | | | 1 | | | |
| Ta₂O₅ | | | | | 1 | | | | |
| Sum | 100 | 100 | 100 | 100 | 100 | 100 | 100 | 100 | 100 |
| nd | 1.61 | 1.62 | 1.62 | 1.60 | 1.66 | 1.61 | 1.60 | 1.61 | 1.65 |
| vd | 59 | 58 | 60 | 60 | 51 | 59 | 47 | 44 | 45 |
| Tg [° C.] | 643 | 640 | 636 | 493 | 639 | 554 | 531 | 580 | 569 |
| CTE_{20/300} [ppm/K] | 7.4 | 7.7 | 7.3 | 8.9 | 7.6 | 9.0 | 8.5 | 8.3 | 9.5 |
| specific density [g/cm³] | 3.5 | 3.6 | 3.6 | 3.0 | 3.8 | 2.9 | 3.3 | 2.9 | 3.3 |
| τ_{i 2 mm 420 nm} [%] | 99.9 | 99.8 | 99.8 | 99.9 | 99.8 | 99.9 | 99.9 | 99.5 | 99.5 |

TABLE 4
Melting examples lanthanum borosilicates (in wt-%)

| | Example | | | | | | | | | |
|---|---|---|---|---|---|---|---|---|---|---|
| | 19 | 20 | 21 | 22 | 23 | 24 | 25 | 26 | 27 | 28 |
| SiO₂ | 12 | 19 | 33 | 10 | 20 | 13 | 9 | 25 | 31 | 24 |
| B₂O₃ | 22 | 26 | 12 | 28 | 2 | 27 | 50 | 5 | 14 | 28 |
| Al₂O₃ | 1 | | | | | 3 | | | 1 | 3 |
| Li₂O | | | | | | | | 1 | 2 | 1 |
| Na₂O | | | | | 2 | | | | | 1 |
| K₂O | 1 | 2 | | | | | | | | |
| MgO | | | | | 5 | | | 5 | 3 | |
| CaO | | | | | | 35 | 27 | 23 | 2 | 10 |
| BaO | 45 | 50 | 36 | 50 | 21 | 1 | 0.5 | 1 | 43 | 8 |
| SrO | | | | | | 10 | | 2 | | 10 |
| TiO₂ | | | | | 12 | | | 10 | 1 | |
| ZrO₂ | 2 | | 3 | | 6 | 2 | 0.5 | 3 | | 1 |
| La₂O₃ | 15 | 3 | 16 | 12 | 25 | 9 | 11 | 13 | 3 | 12 |
| Y₂O₃ | | | | | | | 2 | 1 | | |
| Yb₂O₃ | | | | | | | | 1 | | |
| Gd₂O₃ | | | | | | | | 1 | | 2 |
| Ta₂O₅ | 2 | | | | | | | 1 | | |
| Nb₂O₅ | | | | | 7 | | | 8 | | |
| Sum | 100 | 100 | 100 | 100 | 100 | 100 | 100 | 100 | 100 | 100 |
| Nd | 1.68 | 1.64 | 1.65 | 1.67 | 1.85 | 1.66 | 1.64 | 1.80 | 1.64 | 1.62 |
| Vd | 55 | 60 | 56 | 57 | 32 | 57 | 54 | 35 | 55 | 60 |
| Tg [° C.] | 615 | 639 | 689 | 608 | 683 | 616 | 667 | 651 | 643 | 605 |
| CTE_{20/300} [ppm/K] | 9.3 | 8.1 | 7.4 | 9.0 | 8.4 | 8.4 | 7.6 | 8.6 | 7.6 | 7.2 |
| specific density [g/cm³] | 4.1 | 3.7 | 3.8 | 4.0 | 4.4 | 3.8 | 4.2 | 3.6 | 3.6 | 3.4 |
| τ_{i 2 mm 420 nm} [%] | 99.6 | 99.7 | 99.8 | 99.8 | 97.9 | 99.9 | 98.2 | 99.1 | 99.8 | 99.8 |

TABLE 5
Melting examples titanium silicates (in wt-%)

| | Example | | | | | | |
|---|---|---|---|---|---|---|---|
| | 29 | 30 | 31 | 32 | 33 | 34 | 35 |
| SiO₂ | 50 | 65 | 70 | 58 | 56 | 52 | 50 |
| B₂O₃ | 10 | 1 | | | 4 | 2 | 2 |
| Al₂O₃ | 8 | | 1 | 7 | | | 0.5 |
| Li₂O | | | 1 | | | 0.5 | |
| Na₂O | | 9 | 15 | 7 | 10 | | |
| K₂O | 20 | 11 | 3 | 11 | 9 | 23 | 22 |
| TiO₂ | 10 | 11 | 7 | 14 | 20 | 22 | 25 |
| ZrO₂ | 2 | 3 | 3 | 3 | 1 | 0.5 | 0.5 |
| Sum | 100 | 100 | 100 | 100 | 100 | 100 | 100 |
| nd | 1.60 | 1.60 | 1.60 | 1.61 | 1.62 | 1.60 | 1.60 |
| vd | 44 | 46 | 44 | 41 | 36 | 37 | 35 |
| Tg [° C.] | 447 | | | | 577 | 463 | 472 |
| CTE_{20/300} [ppm/K] | 9 | | | | 9.1 | 9.9 | 10.2 |
| specific density [g/cm³] | 3.2 | | | | 2.7 | 2.7 | 2.7 |
| τ_{i 2 mm 420 nm} [%] | 99.9 | | | | 99.8 | 99.7 | 99.8 |

TABLE 6
Melting examples alkaline earth metal titanium silicates (in wt-%)

| | Example | | | | | | | | | |
|---|---|---|---|---|---|---|---|---|---|---|
| | 36 | 37 | 38 | 39 | 40 | 41 | 42 | 43 | 44 | 45 |
| SiO₂ | 45 | 33 | 26 | 40 | 40 | 34 | 50 | 31 | 25 | 41 |
| B₂O₃ | | 1 | 8 | 3 | 3 | | 5 | 1 | | 2 |
| Al₂O₃ | | | | 3 | | | | | 0.5 | |
| Li₂O | 2 | | | | | | | | | |
| Na₂O | 3 | 12 | 8 | 10 | 13 | 12 | 8 | 10 | 12 | 9 |
| K₂O | 10 | 6 | 5 | 7 | 8 | 6 | 5 | 6 | 1 | 8 |
| MgO | 5 | | | | | | | | | |
| CaO | | 2 | 1 | 3 | 2 | 1 | | 1 | 1 | 1 |
| BaO | 18 | 9 | 12 | 4 | 4 | 7 | 8 | 11 | 16 | 7 |
| SrO | | | | | | | 3 | | | 2 |
| ZnO | | | | | | | | | | |
| TiO₂ | 15 | 28 | 24 | 20 | 25 | 30 | 21 | 23 | 35 | 26 |
| ZrO₂ | 2 | | 8 | 5 | | | | 8 | | 3 |
| Nb₂O₅ | | 9 | | 5 | | 8 | | 4 | 4.5 | 1 |
| La₂O₃ | | | 2 | | | 2 | | | 1 | |
| Y₂O₃ | | | 2 | | 2 | | | 2 | 1 | |
| Yb₂O₃ | | | 2 | | 2 | | | | 1 | |
| Gd₂O₃ | | | 2 | | | | | 2 | 1 | |
| Ta₂O₅ | | | | | 1 | | | 1 | 1 | |
| Sum | 100 | 100 | 100 | 100 | 100 | 100 | 100 | 100 | 100 | 100 |
| nd | 1.66 | 1.76 | 1.81 | 1.69 | 1.69 | 1.76 | 1.67 | 1.78 | 1.85 | 1.71 |
| vd | 36 | 27 | 25 | 31 | 31 | 27 | 33 | 26 | 24 | 30 |
| Tg [° C.] | 619 | 570 | 589 | 552 | 524 | 566 | 434 | 591 | 630 | 578 |
| CTE_{20/300} [ppm/K] | 8.1 | 10.9 | 10.3 | 9.7 | 11.1 | 10.9 | 8.6 | 10.1 | 9.9 | 9.7 |
| specific density [g/cm³] | 3.2 | 3.2 | 3.4 | 3.1 | 2.9 | 3.1 | 4.0 | 3.3 | 3.5 | 3.0 |
| τ_{i 2 mm 420 nm} [%] | 99.1 | 98.2 | 98.3 | 98.7 | 99.2 | 98.9 | 99.8 | 99.2 | 97.3 | 99.4 |

1-13. (canceled)

14. A transparent layer composite assembly, comprising a conductive transparent oxide layer, a semiconductor layer, and a substrate layer, wherein the substrate layer comprises an opto-technical hybrid glass having a refractive index of greater than 1.6.

15. The assembly according to claim 14, wherein the opto-technical hybrid glass is a lanthanum borate glass.

16. The assembly according to claim 14, wherein the opto-technical hybrid glass is a borosilicate glass.

17. The assembly according to claim 14, wherein the opto-technical hybrid glass is a silicate glass.

18. The assembly according to claim 14, wherein the refractive index is greater than or equal to 1.8.

19. The assembly according to claim 14, wherein the opto-technical hybrid glass is free, except for unavoidable impurities, of redox-active oxides selected from the group consisting of lead, arsenic, antimony, and combinations thereof.

20. The assembly according to claim 14, wherein the transparent oxide layer comprises indium tin oxide.

21. The assembly according to claim 14, comprising a refractive index difference between the conductive transparent oxide layer and the substrate layer of at most 0.45.

22. The assembly according to claim 14, wherein the semiconductor layer comprises an organic semiconductor.

23. The assembly according to claim 14, further comprising a cathode layer.

24. The assembly according to claim 23, wherein the assembly comprises an OLED.

25. The assembly according to claim 23, wherein the assembly comprises a solar module.

26. A process for producing a layer composite assembly, comprising the steps of:
using a flat glass process to prepare an opto-technical hybrid glass having a refractive index of greater than 1.6;
using the opto-technical hybrid glass as a substrate layer for a conductive transparent oxide layer and a semiconductor layer to form the layer composite assembly.

27. The process according to claim 26, wherein the flat glass process is a float process.
